(19) United States
(12) Patent Application Publication
(10) Pub. No.: US 2008/0224156 A1
(43) Pub. Date: Sep. 18, 2008

(54) Luminescent Diode Provided with a Reflection- Reducing Layer Sequence

(75) Inventors: Ines Pietzonka, Regensburg (DE); Wolfgang Schmid, Deuerling/Hillohe (DE); Ralph Wirth, Mintraching (DE)

Correspondence Address: COHEN, PONTANI, LIEBERMAN & PAVANE LLP, 551 FIFTH AVENUE, SUITE 1210, NEW YORK, NY, 10176, US

(73) Assignee: OSRAM OPTO SEMICONDUCTORS GMBH, Regensburg (DE)

(21) Appl. No.: 11/659,066

(22) PCT Filed: Jun. 15, 2005
(86) PCT No.: PCT/DE05/01065

§ 371 Date: Apr. 29, 2008

(30) Foreign Application Priority Data
Jul. 30, 2004 (DE) 10 2004 037 100.8
Aug. 24, 2004 (DE) 10 2004 040 968.4

(51) Int. Cl. H01L 33/00

(52) U.S. Cl. 257/98; 257/E33.005

(57) ABSTRACT

A luminescence diode (1) having an active zone (7) which emits electromagnetic radiation in a main radiating direction (15). A reflection-reducing layer sequence (16) is arranged downstream of the active zone (7) in the main radiating direction (15). The reflection-reducing layer sequence includes a DBR mirror (13), which is formed by at least one layer pair (11, 12), an antireflective layer (9) downstream of the DBR mirror (13) in the main radiating direction (15) and an intermediate layer (14) arranged between the DBR mirror (13) and the antireflective layer (9).

This patent application claims the priority of the German patent applications 10 2004 037 100.8 and 10 2004 040 986.4, the disclosure content of which is hereby incorporated by reference.

The invention relates to a luminescence diode according to the preamble of patent claim 1.

In luminescence diodes, a DBR mirror (distributed Bragg reflection mirror) is often used to increase efficiency. A DBR mirror generally includes a plurality of layer pairs comprising epitaxially produced semiconductor layers, which differ in terms of their refractive index and whose optical thickness, that is to say the product of the refractive index of the respective layer and the layer thickness, corresponds in each case to a quarter of the wavelength of the radiation emitted by the luminescence diode. Arranging a DBR mirror of this type between the substrate of the luminescence diode and the active layer can have the effect, in particular, that radiation emitted in the direction of the substrate is reflected back, thus reducing losses on account of absorption in the substrate.

However, the chip surface intended for coupling out radiation also has a certain reflectivity on account of the refractive index difference with respect to the surrounding medium, which may be a potting composition, in particular an epoxy resin, such that, in interaction with the DBR mirror, a resonator is produced. Undesired resonances can occur in the emission spectrum of the luminescence diode on account of this resonator. The resonance effect can even lead to the emission spectrum of the luminescence diode having a plurality of intensity maxima at different wavelengths and/or emission angles. This has a particularly disturbing effect when luminescence diodes are used in optical measurement methods.

These resonances generally average out in an integral measurement of the emission spectrum over a wide angular range, since the resonance spectrum of the resonator is strongly angle-dependent. However, the resonances are registered when the light emitted into a small solid angle range is detected. In measurement methods with a small numerical aperture, i.e. in which the radiation emitted by a luminescence diode is detected within a small angular range, it is therefore desirable to avoid resonances of this type.

The problem of undesired resonances is reduced in conventional luminescence diodes, for example, by growing relatively thick layers, so-called window layers, above the active zone. Window layers of this type are used both for current spreading and also for coupling out light. The thickness of the layers causes the resonances to lie spectrally so close together that they generally have no disturbing effect in applications. Furthermore, layers of this type are often also not planar, either as a result of specific processing steps or on account of the layer growth itself, whereby the resonances are also counteracted. However, the growth of thick layers of this type is associated with a high production outlay and thus high costs.

The invention is based on the object of providing a luminescence diode, in which resonances in the emission spectrum are reduced with a relatively low production outlay.

This object is achieved by means of a luminescence diode having the features of patent claim 1. The dependent claims relate to advantageous embodiments and further developments of the invention.

In a luminescence diode having an active zone which emits electromagnetic radiation in a main radiating direction, a reflection-reducing layer sequence being arranged downstream of the active zone in the main radiating direction, the reflection-reducing layer sequence includes, according to the invention, a DBR mirror, which is formed by at least one layer pair, an antireflective layer downstream of the DBR mirror in the main radiating direction and an intermediate layer arranged between the DBR mirror and the antireflective layer.

Such a reflection-reducing layer sequence is used to reduce the reflectivity of the layers arranged above the active zone such that undesired resonances in the emission spectrum of the luminescence diode are mostly avoided.

The residual reflectivity of the reflection-reducing layer sequence depends in particular on the number of layer pairs of the DBR mirror. It has proven advantageous for the latter to be formed by between one (inclusive) and ten (inclusive) layer pairs, particularly preferably between one (inclusive) and four (inclusive) layer pairs.

The optical thickness of the intermediate layer is preferably equal to half the wavelength of the emitted radiation. It is furthermore advantageous if the optical thickness of the antireflective layer is equal to an odd-numbered multiple of a quarter of the wavelength λ of the emitted radiation, i.e. for example ¼λ, ¾λ or 5/4λ. These layer thicknesses permit a particularly good reflection reduction to be achieved. The intermediate layer is preferably a semiconductor layer and can be epitaxially grown directly onto the semiconductor layers of the DBR layer with advantageously low production outlay.

The antireflective layer is, for example, a dielectric layer and can, in particular, include a silicon oxide or a silicon nitride. A radiation-transmissive conductive oxide (TCO—transparent conductive oxide), in particular ZnO, is also suitable. The antireflective layer can also be doped, for example with aluminum. This is advantageous in particular if partial regions of the antireflective layer are provided with electrical contacts, since the antireflective layer can in this case act as current expansion layer at the same time. An Al-doped ZnO layer is particularly suitable for this purpose. The antireflective layer can furthermore also form an ohmic contact to the intermediate layer which lies beneath it.

The luminescence diode is preferably embedded in a potting composition, for example an epoxy resin. This, firstly, reduces the refractive index difference with respect to a surrounding medium and, secondly, protects the luminescence diode from environmental influences. The potting composition can furthermore also include a luminescence conversion material in order to shift the wavelength of the radiation emitted by the luminescence diode toward larger wavelengths. Suitable luminescence conversion materials, such as YAG:CE (Y₃Al₅O₁₂:Ce³⁺), are described, for example, in WO 98/12757, whose content is in this respect hereby incorporated by reference.

The reflection-reducing layer sequence according to the invention is particularly advantageous for luminescence diodes in which a second mirror, in particular a second DBR mirror, is arranged between a substrate and the active zone. In this case, the radiation emitted by the luminescence diode is prevented from penetrating into the substrate by the second mirror, wherein at the same time the risk that undesired resonances will occur in the emission spectrum is reduced by the reflection-reducing layer sequence as compared to luminescence diodes that have no or a conventional means of reducing reflection. The effect of the reflection-reducing layer sequence according to the invention is in this case independent of the distance of the reflection-reducing layer sequence from the second mirror and/or from the active zone.

The invention is, however, not limited to luminescence diodes which have a substrate and a second mirror applied thereon. It is rather the case that the luminescence diode can also comprise a so-called thin-film semiconductor body, in which an epitaxial layer sequence grown onto a growth substrate has been separated from the growth substrate and mounted on a carrier body. Thin-film semiconductor bodies of this type often include, on the side facing the carrier body, a reflective layer which can likewise form a resonator with the opposite surface, which is generally intended for coupling out radiation.

The total thickness of the reflection-reducing layer sequence is advantageously less than 2000 nm. Thus, the production outlay is comparatively low when compared to luminescence diodes in which undesired resonances in the emission spectrum are reduced by the application of very thick layers.

The invention is explained in more detail below on the basis of exemplary embodiments in conjunction with FIGS. 1 to 6, in which:

FIG. 1 shows a schematic of a cross section through an exemplary embodiment of a luminescence diode in accordance with the invention,

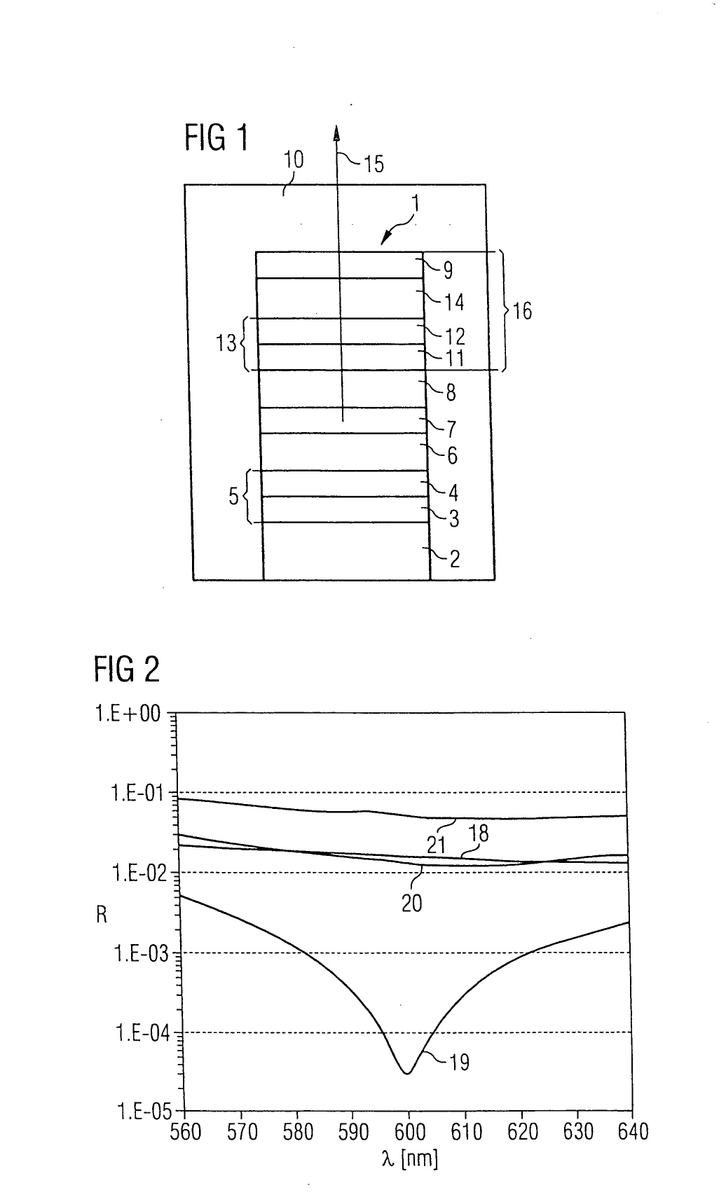

FIG. 2 shows a graph of the reflectivity R of a reflection-reducing layer sequence as a function of the wavelength λ for different numbers of layer pairs of the DBR mirror when an SiN antireflective layer is used,

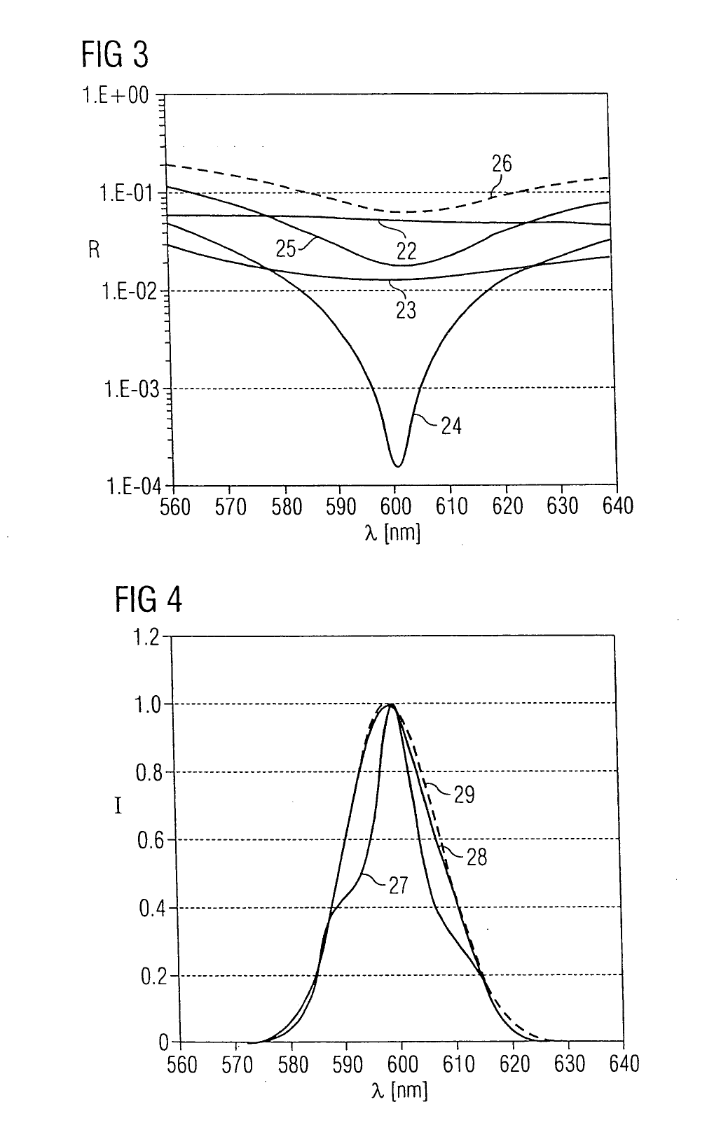

FIG. 3 shows a graph of the reflectivity R of a reflection-reducing layer sequence as a function of the wavelength λ for different numbers of layer pairs of the DBR mirror when a ZnO antireflective layer is used,

FIG. 4 shows a graph of the intensity I of the emitted radiation as a function of the wavelength λ without taking reflection losses into account when a conventional antireflection layer is used and when a reflection-reducing layer sequence according to the invention having an SiN antireflective coat is used,

FIG. 5 shows a graph of the intensity I of the emitted radiation as a function of the wavelength λ without taking reflection losses into account when a conventional antireflection layer is used and when a reflection-reducing layer sequence according to the invention having a ZnO antireflective coat is used, and

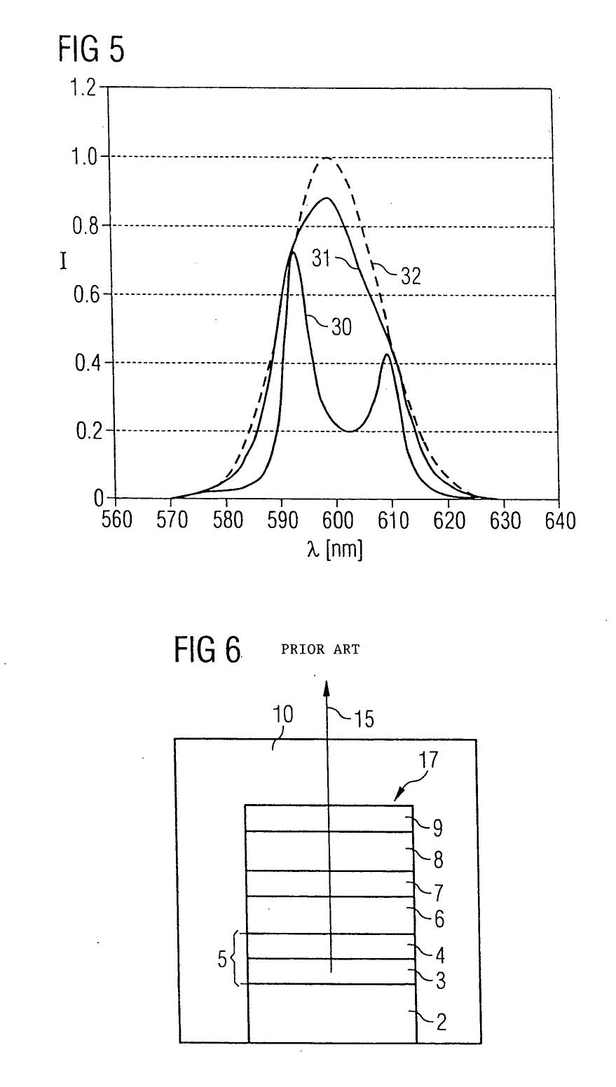

FIG. 6 shows a schematic of a cross section through a luminescence diode according to the prior art.

Identical or identically acting elements are provided with the same reference symbols in the figures.

The luminescence diode 17 corresponding to the prior art and illustrated in FIG. 6 includes a substrate 2 and a DBR mirror 5, which is applied on the substrate 2 and is formed by a plurality of layer pairs of the epitaxially applied semiconductor layers 3 and 4. Radiation emitted in the direction of the substrate 2 is reflected back by the DBR mirror 5. The luminescence diode further includes a radiation-emitting active zone 7, which is arranged between cladding layers 6, 8 and emits radiation in a main radiating direction 15.

The luminescence diode 17 is embedded in a potting composition 10. An antireflective layer 9 is provided in order to reduce reflection losses at the interface between the semiconductor material and the potting composition 10. Despite the antireflective layer 9, a resonator may be produced on account of the residual reflectivity at the interfaces between the antireflective layer 9 and the potting composition 10 and/or the interface between the potting composition 10 and a surrounding medium, for example air, in conjunction with the DBR mirror 5 and this can cause the occurrence of undesired resonances in the emission spectrum of the luminescence diode.

The luminescence diode 1 according to the invention illustrated in FIG. 1 includes a substrate 2, which may be, for example, a GaAs substrate. A DBR mirror 5, which is formed by a plurality of layer pairs of the epitaxially applied semiconductor layers 3 and 4, is applied onto the substrate. A layer pair can, for example, include in each case an Al_{0.5}Ga_{0.5}As layer 3 and an Al_{0.95}Ga_{0.05}As layer 4. The number of layer pairs of the DBR mirror 5 is, for example, approximately 20.

Radiation emitted in the direction of the substrate 2 is reflected back by the DBR mirror 5. In this way, the intensity of the radiation emitted in the main radiating direction 15 is increased and absorption losses in the substrate 2 are reduced.

The luminescence diode 1 furthermore includes a radiation-emitting active zone 7. This zone 7 can, for example, include a layer composed of In_{1-x-y}GaₓAl_{y}P, where 0≦x≦1, 0≦y≦1 and x+y≦1, with a thickness of approximately 0.2 μm in order to achieve an emission wavelength of approximately 600 nm. The active zone can alternatively also include other semiconductor materials and have a different emission wavelength. The active zone 7 is arranged, for example, between a p-type cladding layer 6 and an n-type cladding layer 8, which each have a thickness of approximately 0.8 μm.

The luminescence diode 1 can, for example, be embedded in a potting composition 10, in particular an epoxy resin.

In order to avoid undesired resonances in the emission spectrum, the luminescence diode 1 according to the invention includes a reflection-reducing layer sequence 16. The reflection-reducing layer sequence 16 includes a DBR mirror 13, which is downstream of the active zone 7 in the main radiating direction 15 and is formed by one or more layer pairs. The DBR mirror 13 is advantageously produced from epitaxially grown semiconductor layers 11, 12, whose optical thickness corresponds to a quarter of the wavelength of the emitted radiation. The DBR mirror 13 can, for example, be produced from at least one layer pair of in each case an Al_{0.5}Ga_{0.5}As semiconductor layer 11 and an Al_{0.95}Ga_{0.05}As semiconductor layer 12.

The reflection-reducing layer sequence 16 furthermore includes an antireflective layer 9 adjoining the potting composition, the optical thickness of the antireflective layer 9 likewise preferably corresponding to a quarter of the wavelength of the emitted radiation or alternatively to some other odd-numbered multiple of the wavelength λ such as ¾λ or 5/4λ. The antireflective layer can include, in particular, a silicon nitride, a silicon oxide or a zinc oxide.

The reflection-reducing layer sequence 16 includes an intermediate layer 14 between the DBR mirror 13 and the antireflective layer 9, with the intermediate layer 14 including, for example, Al_{0.5}Ga_{0.5}As and having an optical thickness which corresponds approximately to half the wavelength of the emitted radiation. The reflection-reducing layer sequence forms, in this manner, a reflection-reducing resonator.

Reducing the reflection by means of the reflection-reducing layer sequence 16 according to the invention is critically dependent on the number of layer pairs of the DBR mirror 13. This is shown clearly in the simulation of the reflectivity of the layers arranged above the active zone 7 as illustrated below.

A simulation of the reflectivity R of a reflection-reducing layer sequence as a function of the wavelength λ for different numbers of layer pairs of the DBR mirror is illustrated in FIG. 2. The simulation assumed that the antireflective layer 9 is an SiN layer having a refractive index n=2.05. The reflectivity R was simulated as a function of the wavelength λ without a DBR mirror (curve 18), for a DBR mirror 13 having one layer pair (curve 19), having two layer pairs (curve 20) and having three layer pairs (curve 21). Accordingly, the optimum reflection reduction is achieved by a DBR mirror 13 having only one layer pair.

A simulation of the reflectivity R of a reflection-reducing layer sequence as a function of the wavelength λ for different numbers of layer pairs of the DBR mirror is illustrated in FIG. 3, the simulation having been based on the antireflective layer 9 including Al-doped ZnO having a refractive index n=1.85. The reflectivity of the layers arranged above the active zone 7 was simulated without a DBR mirror (curve 22), with a DBR mirror having one layer pair (curve 23), having two layer pairs (curve 24), having three layer pairs (curve 25) and having four layer pairs (curve 26). The simulation calculations illustrate that in this case the best reflection reduction is achieved by a DBR mirror 13 having two layer pairs.

Generally, the DBR mirror 13 must, similar to a symmetric Fabry-Perot resonator, have approximately the same reflectivity as an external reflector, which is formed by the layer transitions between the intermediate layer 14 and the antireflective layer 9 and also between the antireflective layer and the potting composition 10 in order to minimize the residual reflectivity. For this reason, an additional layer pair is required in the exemplary embodiment having an antireflective layer 9 composed of ZnO as compared to the exemplary embodiment having an antireflective layer composed of SiN. Since ZnO has a lower refractive index than SiN, the difference in the refractive index of the antireflective layer 9 with respect to the adjoining intermediate layer 14 is larger, which increases the reflectivity of the external reflector. The additional layer pair in the DBR mirror 13 is used to achieve in this case a matching of the reflectivity of the DBR mirror 13 to the external reflector.

For the purpose of achieving an optimum reflection reduction, the DBR mirror 13 can also include layers 11, 12 whose optical thicknesses deviate from λ/4. The thickness of the layer 11 could be, for example, 1.2 λ/4 and the thickness of the layer 12 0.8 λ/4. In this manner, too, it is possible to match the reflectivity of the DBR mirror 13 to the reflectivity of the external reflector. The refractive index difference of the layers 11, 12 of the DBR mirror 13 could alternatively also be varied in order to achieve optimum reflection reduction. In AlGaAs semiconductor layers, by way of example, this is possible by varying the Al content.

FIG. 4 illustrates a simulation of the intensity I of the emission (in arbitrary units) for a luminescence diode having an SiN antireflective coat. Whereas the emission spectrum without a DBR mirror 13 according to the invention (curve 27) is considerably influenced by resonances, the emission spectrum of a luminescence diode having a reflection-reducing layer sequence according to the invention (illustrated in curve 28) deviates only insignificantly from the emission spectrum illustrated in curve 29, in which no external reflections were taken into account.

The effect of the reflection-reducing layer sequence 16 according to the invention is even clearer in the emission spectra (illustrated in FIG. 5) of a luminescence diode having an antireflective layer 9 composed of ZnO. Whereas the emission spectrum simulated in the curve 30 without a reflection-reducing layer sequence 16 according to the invention has two maxima, the emission spectrum simulated in the curve 31 having a reflection-reducing layer sequence 16 according to the invention shows a similar profile to the emission spectrum (simulated in the curve 32) of the active zone 7, without taking into account external influences.

The reflection-reducing layer sequence 16 according to the invention is advantageous particularly because double or even multiple maxima in the emission spectrum prove to be very disturbing when using a luminescence diode in precise optical measurement methods, in particular in measurement methods in which differential signals are registered, for example in temperature or thermal resistance measurement methods.

The invention is not limited by the description on the basis of the exemplary embodiments. It is rather the case that the invention comprises any novel feature and any combination of features, which includes in particular any combination of features in the patent claims, even if this feature or this combination is not itself explicitly mentioned in the patent claims or exemplary embodiments.

1. A luminescence diode having an active zone which emits electromagnetic radiation in a main radiating direction, a reflection-reducing layer sequence being arranged downstream of the active zone in the main radiating direction, wherein the reflection-reducing layer sequence comprises:
a DBR mirror, which is formed by at least one layer pair,
an antireflective layer downstream of the DBR mirror in the main radiating directions, and
an intermediate layer arranged between the DBR mirror and the antireflective layer.

2. The luminescence diode as claimed in claim 1, wherein the DBR mirror is formed by between 1 (inclusive) and 10 (inclusive) layer pairs.

3. The luminescence diode as claimed in claim 1, wherein the optical thickness of the intermediate layer is equal to half the wavelength of the emitted radiation.

4. The luminescence diode as claimed in claim 1, wherein the optical thickness of the antireflective layer is equal to an odd-numbered multiple of a quarter of the wavelength of the emitted radiation.

5. The luminescence diode as claimed in claim 1, wherein the antireflective layer is a dielectric layer.

6. The luminescence diode as claimed in claim 5, wherein the antireflective layer includes a silicon oxide or a silicon nitride.

7. The luminescence diode as claimed in claim 1, wherein the antireflective layer includes a radiation-transmissive conductive oxide.

8. The luminescence diode as claimed in claim 7, wherein the radiation-transmissive conductive oxide includes ZnO.

9. The luminescence diode as claimed in claim 1, wherein the antireflective layer is doped.

10. The luminescence diode as claimed in claim 1, wherein the intermediate layer is a semiconductor layer.

11. The luminescence diode as claimed in claim 10, wherein the antireflective layer forms an ohmic contact with the intermediate layer.

12. The luminescence diode as claimed in claim 1, wherein the luminescence diode is embedded in a potting composition.

13. The luminescence diode as claimed in claim 12, wherein the potting composition is an epoxy resin.

14. The luminescence diode as claimed in claim 1, wherein the total thickness of the reflection-reducing layer sequence is less than 2000 nm.

15. The luminescence diode as claimed in claim 1, wherein the luminescence diode has a substrate and a second mirror is arranged between the substrate and the active zone.

16. The luminescence diode as claimed in claim 15, wherein the second mirror is a DBR mirror.

17. The luminescence diode as claimed in claim 1, wherein the luminescence diode comprises a thin-film semiconductor body.
